(19) United States
(12) Patent Application Publication
(10) Pub. No.: US 2007/0254096 A1
(43) Pub. Date: Nov. 1, 2007

(54) Apparatus and Method for Cleaning at Least One Process Chamber for Coating at Least One Substrate

(75) Inventors: Ronald Hepper, Mistelbach (DE); Klaus Kallee, Landsberg (DE)

Correspondence Address: WORKMAN NYDEGGER, 60 EAST SOUTH TEMPLE, 1000 EAGLE GATE TOWER, SALT LAKE CITY, UT, 84111, US

(73) Assignee: WIESSNER GMBH, Bayreuth (DE)

(21) Appl. No.: 10/596,406

(22) PCT Filed: Jan. 15, 2004
(86) PCT No.: PCT/EP04/00250

§ 371 Date: Jun. 15, 2007

(30) Foreign Application Priority Data
Dec. 11, 2003 (DE) 103 58 275.4

(51) Int. Cl. B08B 5/00; B08B 9/00; C23C 16/44

(52) U.S. Cl. 427/237; 134/1; 134/106; 134/107; 134/115 R; 134/133; 134/166 R; 134/19; 134/22.1

(57) ABSTRACT

Apparatus and methods in accordance with implementations of the present invention can be configured for cleaning at least one process chamber, which in turn is configured for coating at least one substrate. In general, the at least one substrate will be made from glass, and the at least one process chamber can be purged with a conditioned purge gas prior to a coating operation.

The invention relates to an apparatus and a method for cleaning at least one process chamber for coating at least one substrate, in particular made from glass.

By applying functional layers to a glass surface, it is possible to impart various properties to the glass. For example, glasses for optical applications, mirror glasses or glasses which provide protection against heat and sun, for example for window panes, as facade cladding or for displays, can be produced from hollow glasses or from flat glasses by application of layers, in particular metallic, polymer or hard-material layers.

A layer can be applied in various ways from a solution or from the vapor phase. The deposition of coating materials from the vapor phase in particular allows the generation of highly uniform and, if desired, also very thin layers on the glass. It is in this way particularly advantageously also possible to obtain multiple layers comprising different materials. The vapor deposition processes include physical vapor deposition (PVD) processes, such as vacuum coating or sputtering, and chemical vapor deposition (CVD) processes.

In the case of vacuum coating, in particular high-vacuum coating, accurately calculated quantities of the respective coating material which can be vaporized, in particular metal, are completely vaporized in a process chamber at pressures between 10−8 and 10−9 bar. For this purpose, the coating material is heated in a crucible under a high vacuum, for example by resistive or inductive heating. The coating material in vapor form is then deposited very uniformly on the relatively cold substrate, the glass.

Sputtering can be used, for example, to apply metal layers or metal oxide layers to the substrate. For this purpose, in a closed system the coating material, in particular metal, in the form of a plate (target) is connected as cathode. The substrate, in particular glass, and a positively charged anode are arranged opposite it. The residual gas in a process chamber which has been evacuated to a pressure of from 10−4 to 10−6 bar is preferably a noble gas, for example argon (for reactive sputtering, it is also possible to introduce a reaction gas). A voltage is applied between anode and cathode. Electrons are accelerated toward the anode and ionize argon atoms located in between by colliding with them. The positively charged argon atoms are accelerated toward the cathode in the electric field. The mechanical transfer of momentum of the ions to the target leads to sputtering of the target atoms, which are deposited on the opposite substrate, for example a pane of glass, and form a film. During this operation, electrons are released as well as neutral atoms of the target. In this way, a steady-state plasma is formed between the two electrodes. The most common processes are DC sputtering, RF sputtering, magnetron sputtering, gas flow sputtering, reactive sputtering and bias-assisted sputtering.

Chemical vapor deposition (CVD) normally first of all involves a reaction between two starting materials in the gas space, with the reaction product then being deposited on the substrate. In the CVD process, the process chamber is preferably evacuated prior to the introduction of the gaseous starting materials, in order to remove disruptive foreign substances; the process itself can take place at standard pressure or at a reduced pressure compared to ambient pressure (10−5 to 10−2 bar).

One feature common to vapor deposition processes is that very low pressures (vacuum) are generated. In this way, inter alia, the disruptive influence of undesirable substances in the vapor phase during a coating operation is reduced. A working operation or coating operation comprises at least setting the desired process parameters, which may include the evacuation of the process chamber or coating chamber, and the introduction of at least one substrate that is to be coated into the coating chamber, the coating process from the vapor phase, which preferably takes place at subatmospheric pressure or in a partial vacuum, and the removal of the substrate from the coating chamber. Moreover, the coating process can take place continuously or discontinuously. Prior to the coating operation or prior to the coating process, the coating installation is evacuated in order to remove disruptive compounds, such as water, hydrogen, nitrogen, oxygen or other compounds or gases, for example used in a previous process, from the process chamber.

Between the individual batches of a discontinuous coating installation or during a substrate or product change in a continuous coating installation and for cleaning or maintenance work, it may be advantageous to open the coating installation. In this case, at least ambient air can enter the process chamber, which once again introduces disruptive gases, water vapor, water or further compounds into the process chamber. The respective process conditions then have to be set again. In this case, the process chamber is first of all emptied or evacuated for a predetermined period of time, for example by means of a suction pump, in order to remove the disruptive foreign substances.

In practice, however, it has been observed that generally not all the foreign substances are removed during the evacuation of the process chamber. For example, during the evacuation of the process chamber, substances which have condensed or been adsorbed on or in inner walls or internal fittings of the process chamber or trapped gases, in particular water or water vapor, but also various other substances or gases, can be transferred into the gas phase of the process chamber, and these substances or gases generally cannot be completely removed by the suction pump within the predetermined pumping time. These substances can then contaminate the process chamber or the substrate introduced into it and therefore have an adverse effect on the subsequent coating process. This leads to a deterioration in the quality of at least the first coated substrates. These substrates which have not been optimally coated are in practice disposed of as scrap.

Furthermore, solid constituents of the coating material may also have been deposited on the inner walls and internal fittings of the process chamber during the coating process, and these solid constituents, if they drop onto the substrate, likewise lead to a certain amount of scrap.

It is an object of the invention to provide a method and an apparatus for cleaning at least one process chamber for coating a substrate which at least partially overcome or at least mitigate the abovementioned drawbacks of the prior art.

This object is solved with regard to the method by the features of patent claim 1 and with regard to the apparatus by the features of patent claim 21. Advantageous configurations and refinements will emerge from the claims which are respectively dependent on claim 1 and claim 21.

In the method as claimed in claim 1 for cleaning at least one process chamber for coating at least one substrate, in particular made from glass, the at least one process chamber is purged with a conditioned purge gas prior to a coating operation.

The apparatus as claimed in claim 21 is suitable and intended for cleaning at least one process chamber for coating at least one substrate, in particular made from glass, and in particular for use in the method as claimed in claim 1 or one or more of the claims which are dependent on claim 1, and this apparatus comprises at least one purge device for introducing a conditioned purge gas into the at least one process chamber and/or for passing a conditioned purge gas through the at least one process chamber prior to a coating operation.

The substrate is preferably an object made from glass, in particular made from a flat glass or a hollow glass. In general, a defined property or function is imparted to the glass by the application of layers, in particular metallic layers, polymer layers or hard-material layers in a coating operation. The coating operation comprises setting the process parameters, for example pressure and temperature, introducing the substrate into the process chamber and coating the substrate, and also removing the coated substrate from the process chamber. The coating operation preferably takes place at very low pressures, but may also be carried out at any other desired pressures, for example ambient pressure or standard pressure. It is preferable for chemical and physical processes for deposition from the vapor phase as are known from the prior art, for example CVD processes or PVD processes such as vacuum coating or sputtering, to be used for the coating of the substrates.

The coating may take place in just one process chamber, but it is also possible for the substrate to pass through a plurality of process chambers, with in each case the same coating material or different coating materials being applied to the substrate. If the coating takes place at very low pressure (vacuum), pressure locks are located at the entry and exit of the process chambers, so that the process conditions in the process chambers remain unchanged during introduction and removal of a substrate.

The purging of the process chamber with conditioned purge gas takes place prior to the coating operation, i.e. before the process parameters are set and before the substrate is introduced. This means that the process chamber is preferably purged at ambient pressure or standard pressure in order to discharge impurities, such as water, water vapor or other liquids and gases, so that on evacuation they cannot be desorbed, evaporated or escape into the process chamber. For this process, the purge gas can be conditioned with regard to the moisture content and/or the temperature and/or the pressure and/or the gas composition as conditioning variable(s) and should preferably be free of other impurities. Furthermore, the purge gas can originate from a process which precedes the coating or from a separate source. After the purge has passed through the process chamber(s), it can either be reprocessed or disposed of.

Therefore, a concept on which the invention is based is that of removing the maximum possible amounts of impurities or foreign substances from the process chamber by purging the process chamber prior to commencement of a coating operation, in order in this way to allow an optimum coating process with reduced scrap rates and preferably with no scrap whatsoever. It is not generally possible to intervene in the coating process in order to reduce the extent to which the coating process is adversely affected by foreign substances, since predetermined process parameters need to be maintained to achieve the desired coating result or the desired layer. Therefore, by purging the process chamber prior to the coating operation, it is possible to ensure that impurities or foreign substances which have been trapped, condensed or adsorbed on or in inner walls or internal fittings of the process chamber and which, if the coating process takes place at very low pressures, can pass into the vapor phase as a result of the reduced pressure and can be deposited on the substrate or influence the coating process in some other way, are removed from the installation with the conditioned purge gas before the coating operation begins. For this purpose, by way of example there is a drop in concentration between the foreign substances in the process chamber and in the purge gas, so that the foreign substances pass into the purge gas having the lower concentration. The cleaning operation or purging operation can be assisted, for example, by increasing the temperature in the process chamber, with the result that firstly the uptake capacity of the purge gas can be increased and secondly the transfer of the foreign substances into the vapor phase can be facilitated.

Moreover, the purge gas stream also allows solid particles, for example loose particles of the coating material which have been deposited on the inner walls or internal fittings of the process chamber, to be at least partially discharged, depending on the respective flow conditions and the particle size.

A further advantage of the method and apparatus according to the invention is that the cleaning operation, i.e. the purging of the process chamber with purge gas, is possible without intervening in the coating process or the coating installation and its control, since the cleaning operation or purging operation takes place independently of the coating process prior to the start of the coating operation, and the devices and means for feeding the purge gas into the at least one process chamber of the coating installation and/or for passing the purge gas through the at least one process chamber do not have to be integrated in the coating installation. Depending on the particular requirements, it is possible to use existing openings and locks for supplying or feeding in the purge gas. The means for supplying and discharging and for conditioning the purge gas are independent of the coating installation and can also be controlled independently. Therefore, the apparatus according to the invention is easy to retrofit to existing coating installations.

Moreover, the method and apparatus according to the invention, during coating, also allow a reduction in the water content in the base layer, a reduction in the red haze in the case of thermally insulating panes, allow the number of pinholes to be minimized in panes with a low transmission, allow the silver crystallinity to be improved and also allow the layer hardnesses and layer quality to be improved.

In a particularly advantageous embodiment of the method according to the invention, the purge gas is conditioned with regard to the moisture content. In general, the relative moisture content of the purge gas, before it enters the at least one process chamber, is set to at most 30%, in particular at most 25%, preferably at most 10% or in special cases even at most 5%. In particular to take up water or water vapor which has been trapped, condensed or adsorbed in or on the inner walls or internal fittings of the process chamber, it is advantageous if the purge gas has a low moisture content or is dried before it is fed into the process chamber. The drying can be carried out by all suitable gas drying methods which are known from the prior art. By way of example, the moisture content can be reduced by adsorption on a suitable medium or by cooling of the gas stream and condensing out the moisture. However, the moisture content of the purge gas can also be increased by suitable methods should it prove advantageous to do so.

It is particularly advantageous if the purge gas, before it enters the at least one process chamber, has foreign substances removed from it, in particular by filtering. This prevents the purge gas from entraining further impurities into the process chamber. All suitable gas purification methods which are known from the prior art can be used to remove foreign substances from the purge gas. By way of example, depending on the desired purity level, the purge gas can be purified using suitable filter elements, such as coarse filters, fine filters or HEPA filters.

It is also advantageous if the temperature of the purge gas, before it enters the at least one process chamber, is set in a predetermined temperature range, preferably to at least a predetermined temperature value, in particular in a temperature range between 20° C. and 90° C., preferably in a temperature range between 60° C. and 80° C. The heated purge gas allows more successful conversion of condensed-out or adsorbed impurities into the vapor phase. The higher the temperature of the purge gas, moreover, the more moisture the purge gas can take up (for water cf. Mollier diagram).

It may also be particularly expedient if the pressure of the purge gas, before it enters the at least one process chamber, is set to a predetermined pressure value, preferably in a pressure range from 0.8 bar to 1.5 bar. The flow velocity in the process chamber can then be set using the pressure. Since the purge gas generally flows through the process chamber at ambient pressure or subatmospheric pressure, it is advantageous if the purge gas flows out of a conditioning device at a higher pressure than ambient pressure, so as to achieve a relatively high flow velocity and a large volumetric flow through the process chamber. Furthermore, however, it may also be advantageous for the purge gas to be passed through the process chamber at a pressure which is reduced compared to ambient pressure or for a reduced pressure to be generated in the process chamber during the purification operation, in order to make it easier for the impurities to pass into the vapor phase.

The purge gas used in the method according to the invention is preferably air, in particular ambient air, and/or an inert gas. Purging with air, in particular ambient air, is preferred, since this is relatively inexpensive, large quantities are available and if appropriate air which has already been conditioned from a process air circuit can be used. Inert gas is preferably used for purging if, for example, no oxygen or other disruptive gases are supposed to be present in the coating process. However, the use of inert gas is generally more expensive than the use of air, in particular ambient air. Furthermore, it is possible to use further gases or gas mixtures as purge gas, which preferably contain one or more constituents of ambient air in any desired, suitable concentration.

In the method according to the invention, in an advantageous embodiment the conditioned purge gas flows, preferably continuously, through the at least one process chamber during a cleaning operation or purging operation. However, it may also be advantageous if at least one cleaning step is carried out by flooding the process chamber with conditioned purge gas and then discharging the purge gas, which may also take place in combination with the abovementioned embodiment of through-flow, for example subsequent flow through the process chamber. This makes it possible to ensure that the impurities are transferred into the conditioned purge gas located in the process chamber and are discharged with the purge gas. In the cleaning step comprising flooding and discharging, by way of example it is also easy to generate a subatmospheric pressure when the purge gas is being pumped out, making it easier for impurities to pass into the vapor phase. It may also be particularly advantageous for the purge gas to flow into the process chamber immediately after a coating operation, with the result that then, during coating in vacuo, the pressure in the process chamber is increased by the purge gas after the coating operation has ended. In this way, depending on the particular coating operation, it is possible to reduce the introduction of impurities into the process chamber in the event of a substrate or product change.

If the coating takes place at very low pressure (vacuum), pressure locks are normally present at the entry and/or exit of the process chambers, through which pressure locks the at least one substrate is introduced into the process chamber and discharged from the process chamber, respectively. The pressure locks prevent the process conditions in the process chambers, in particular the pressure, from changing during the introduction and removal of a substrate. If a plurality of process chambers are connected in series, there is generally likewise at least one pressure lock between these process chambers. This is required in particular if different pressures prevail in the various process chambers of a coating apparatus, as is very often the case. The pressure locks then prevent gas exchange between the process chambers.

The pressure locks can be designed in such a way that the substrate is passed into the pressure lock at the respective ambient pressure, i.e., in particular during introduction into a first process chamber, at approximately standard pressure, and during introduction into a further process chamber, at the respective pressure in the preceding process chamber. Then, the pressure lock is closed and set to the respective pressure of the following process chamber by evacuation or by addition of gas. The pressure chamber is then opened toward the following process chamber, the substrate is introduced into the process chamber and the pressure locks are closed again and returned to the starting pressure by evacuation or by addition of gas, in order to receive a substrate. In the prior art, the respective pressure equalization is generally carried out by the addition of ambient air. In this case, however, foreign substances may enter the pressure lock with the ambient air, and these foreign substances can be entrained into the installation during the method and can therefore affect the coating process.

In a particularly preferred refinement of the method or alternatively in the method claimed in the optionally independent claim 8, therefore, during the cleaning operation the conditioned purge gas is flushed, preferably flows continuously, through a pressure lock arranged at an entry and/or an exit of the at least one process chamber. It is in this way also possible to remove impurities in the pressure lock, which during evacuation of the pressure lock can pass into the gas phase and, for example, contaminate the substrate.

It is particularly advantageous if, moreover, for pressure equalization in the pressure lock, conditioned purge gas flows into the pressure lock and/or if the pressure lock, before the at least one substrate passes into the pressure lock and/or while the at least one substrate is in the pressure lock, is purged with conditioned purge gas.

This firstly makes it possible to prevent foreign substances from penetrating into the pressure lock from the outside, and secondly allows foreign substances which are already present in the pressure lock or foreign substances which have been introduced by the substrate to be removed. In this context, by way of example, it is conceivable first of all for the pressure equalization in the pressure chamber to be carried out using purge gas, and furthermore for the purge gas to flow through the pressure lock for a short time, in order, for example, to remove foreign substances from the gas phase or from a substrate which has already been introduced, and the pressure chamber is then evacuated. In this way, the coating operation can be carried out with virtually complete exclusion of ambient air. The purge gas discharged from the pressure lock can either be discharged to the environment or fed to the purge gas circuit and reconditioned.

It may be particularly expedient if the purge gas is mixed from various gas streams. In this case, by way of example, a gas stream from a process which precedes the coating can be mixed with a purge gas stream made up of conditioned ambient air or conditioned gas, preferably inert gas, in order in this way to reduce the costs of the cleaning operation.

It is also particularly advantageous if the purge gas is passed through a circuit. In this case, the purge gas which emerges from the at least one process chamber is conditioned again with regard to the moisture content and/or the loading with foreign substances and/or the temperature and/or the pressure and/or the gas composition and is fed back to the at least one process chamber or also another process which is independent of the coating.

Prior to the coating operation, the at least one substrate is generally pretreated in a substrate treatment operation which precedes the coating operation, in particular is cleaned in a substrate washing operation, preferably using water or another suitable liquid, and is dried in a subsequent substrate drying operation. It is particularly advantageous if at least some of a conditioned drying gas for drying the at least one substrate in the substrate drying operation and/or at least some of a drying gas which is discharged from the substrate drying operation is at least partly used as purge gas.

Moreover, in a particularly advantageous embodiment, the at least one process chamber is at least partially heated, in particular at least part of at least one process chamber wall, before and/or during the cleaning operation. For this purpose, the heat is preferably supplied from the outside by means of a heating device arranged outside the process chamber. The at least one process chamber is then heated, for example inductively or by radiation or by heat conduction, at least in part to a temperature which is generally between 20° C. and 60° C., in particular between 40° C. and 60° C. The process chamber or the process chamber wall can also be heated to higher temperatures if the materials used to produce the process chamber, in particular for seals and internal fittings arranged at the process chamber wall, permit. The heating of the process chamber may take place continuously before and/or during the entire cleaning operation or may only take place for certain time intervals in order to temporarily assist a cleaning operation.

During the coating process, coating material is generally deposited not only on the substrate but also on the inner walls and/or internal fittings of the process chamber. If a plurality of substrates are coated in succession, it is possible for these deposits to accumulate or build up on the walls or internal fittings until what are known as deposits have been formed. In this case, there is a risk of parts of the deposits coming free in the event of even slight shaking or under the force of gravity, which can then contaminate the substrate or product. These products in practice then have to be disposed of as scrap.

In a particularly preferred refinement of the method and apparatus according to the invention, at least one pulse generator device imparts at least one mechanical pulse to a process chamber wall, in particular an outer wall, of the at least one process chamber before and/or during a coating operation. It is in this way possible to achieve targeted removal of deposits, i.e. to knock off coating material particles or deposits which have been deposited or accumulated on the inner walls and internal fittings of the process chamber.

These features could also be claimed independently in further independent claims, for example in the following form: a method for cleaning at least one process chamber for coating at least one substrate, in particular made from glass, in which at least one pulse generator device, before and/or during a coating operation, imparts at least one mechanical pulse to a process chamber wall, in particular an outer wall, of the at least one process chamber, or an apparatus for cleaning at least one process chamber for coating at least one substrate, in particular made from glass, which comprises a pulse generator device for generating a pulse on a process chamber wall, in particular an outer wall, of the at least one process chamber.

The provision of the mechanical pulse generator allows these deposits to be knocked off at regular intervals or on demand, preferably at a time at which there is no substrate in the process chamber, i.e. before a coating operation or between the coating processes carried out on a plurality of substrates.

It is preferable for the mechanical pulse generator device used to be at least one hammer and/or at least one compressed-air nozzle and/or at least one vibration unit and/or at least one ultrasound generator. Furthermore, the at least one pulse generator device of the apparatus according to the invention may comprise at least one control unit. The mechanical pulse is preferably triggered automatically as a function of at least one process variable. It is particularly advantageous if, moreover, the strength of the mechanical pulse can be set as a function of a degree of contamination. In this case, suitable sensors need to be provided in the process chamber. A process variable which triggers the mechanical pulse or the knocking-off operation is preferably a variable which indicates that there is no substrate in the process chamber at the respective time. Without having to intervene in the coating installation, this could, for example, be a conveying rate of the substrates in the coating installation or a temperature or a pressure in the process chamber. The control unit can be used to control the time at which the pulse is triggered, the strength of the pulse and the duration for which mechanical pulses are generated. For this purpose, it is advantageous if there are means for determining process variables, in particular for detecting a degree of contamination in the process chamber. These may, for example, be optical sensors which have been introduced into the process chamber. Other process variables, such as the conveying rate of the substrates or the temperature or pressure in the process chamber, can if appropriate also be taken from the control device of the coating installation if the control unit of the pulse generator device can, in an advantageous embodiment, be coupled to it.

Furthermore, it may also be possible for at least some of the purge gas which emerges from the at least one process chamber to be used to generate the mechanical pulse, for example to generate a pulse by flowing out of a compressed-air nozzle or by actuating a pneumatic hammer.

In the apparatus as claimed in claim 21, the at least one purge device for introducing a conditioned purge gas into the at least one process chamber and/or for passing a conditioned purge gas through the at least one process chamber preferably comprises at least one purge gas feed line and at least one purge gas delivery unit, in particular a pump and/or a fan, which are arranged upstream and/or downstream of the at least one process chamber as seen in a direction of flow. The direction of flow denotes the direction in which the purge gas flows through the process chambers of the coating installation.

In a particularly advantageous embodiment of the apparatus according to the invention, there is at least one conditioning device for conditioning the purge gas before it enters the process chamber. It is in this case preferably possible to provide at least one conditioning device for the purpose of setting a moisture content of the purge gas, in particular in the form of an adsorption unit or a cooling unit, preferably an absorption refrigeration machine, and/or to provide at least one conditioning device for setting a temperature of the purge gas, in particular in the form of a heating device, and/or to provide at least one conditioning device for setting a pressure of the purge gas, in particular in the form of a compressor, and/or to provide at least one conditioning device for separating foreign substances out of the purge gas, in particular in the form of a filter unit. As described above, all suitable devices which are known from the prior art can be used for this purpose. It is also possible to set more than one property or conditioning variable of the purge gas in a combined conditioning device.

If pressure locks are provided at the entry and/or at the exit of the at least one process chamber, it is particularly advantageous if the apparatus in an advantageous refinement or alternatively the apparatus claimed in the optionally independent claim 25 comprises at least one feed device for introducing the conditioned purge gas into at least one pressure lock arranged at an entry of the process chamber and/or at an exit of the process chamber and/or for passing the conditioned purge gas through the at least one pressure lock and/or at least one discharge device for discharging the purge gas from the at least one pressure lock. Pressure equalization in the pressure lock and/or purging of the pressure lock with conditioned purge gas can then take place via the at least one feed device, which by way of example may comprise at least one feed line and at least one feed unit, such as a fan and/or a pump. The purge gas, which is discharged from the pressure lock by means of the at least one discharge device, which by way of example may comprise at least one discharge line and at least one discharge unit, such as a fan and/or a pump, can be fed back to the at least one conditioning device.

Furthermore, the apparatus preferably comprises at least one heating device for the purpose of heating at least part of at least one process chamber before and/or during a cleaning operation, which is preferably arranged outside the process chamber. The heating device heats the process chamber in particular inductively, by radiation or by heat conduction.

Prior to the coating operation, the substrate is to be treated in a substrate treatment apparatus, so that an optimum coating result can be achieved. For this purpose, by way of example, the substrate or the substrate surface is to be cleaned in a substrate washing apparatus and then dried in a substrate drying apparatus. By way of example, a conditioned gas, preferably air, in particular ambient air, is likewise required for the substrate drying.

In a particularly advantageous embodiment of the apparatus according to the invention, the at least one conditioning device corresponds to at least one conditioning device of a substrate treatment apparatus connected upstream of the at least one process chamber, in particular of a substrate washing apparatus with following substrate drying apparatus. This allows both energy consumption and costs to be reduced.

It is particularly advantageous if there is at least one means for introducing at least some of a drying gas which emerges from the substrate drying apparatus and/or at least some of a drying gas which has been prepared in the at least one conditioning device of the substrate drying apparatus into the process chamber. This means it is possible either for conditioned gas to be mixed with waste gas from the substrate drying apparatus, so as to obtain a purge gas with a moisture content which is still sufficiently low for the purging purposes, or simply some of the drying gas which has been prepared for the substrate drying is branched off and passed as purge gas into the at least one process chamber of the coating installation. If the drying gas which is discharged from the substrate drying apparatus and the purge gas which is discharged from the at least one process chamber are combined again and are fed back to the at least one common conditioning device in order to be reprocessed, it is possible to achieve a very economic circulation.

In the method as claimed in claim 32 for coating at least one substrate, in particular made from glass, in a process chamber, the process chamber, prior to a coating operation, is cleaned by the method as claimed in one or more of claims 1 to 20 and/or using the apparatus as claimed in one or more of claims 21 to 31. It is particularly advantageous if, furthermore, after a cleaning operation the pressure in the process chamber is reduced with respect to ambient pressure, preferably to from 10−7 bar to 10−3 bar, and then a coating process is initiated, in particular a coating process from the vapor phase, preferably a PVD or CVD process.

The apparatus as claimed in claim 34 for coating at least one substrate, in particular made from glass, in a process chamber, in particular for carrying out the method as claimed in claim 32 or claim 33, comprises a separate apparatus for cleaning the process chamber prior to a coating operation by purging with a conditioned purge gas, in particular the apparatus as claimed in one or more of claims 21 to 31.

The invention is explained in more detail below on the basis of exemplary embodiments and with reference to the accompanying drawings, in which:

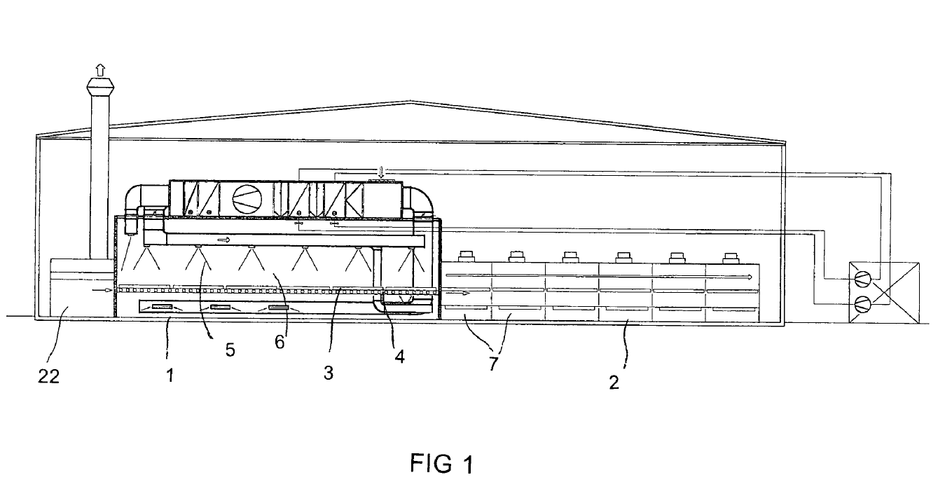

FIG. 1 schematically shows a glass washing and gas drying apparatus with subsequent coating apparatus in accordance with the prior art;

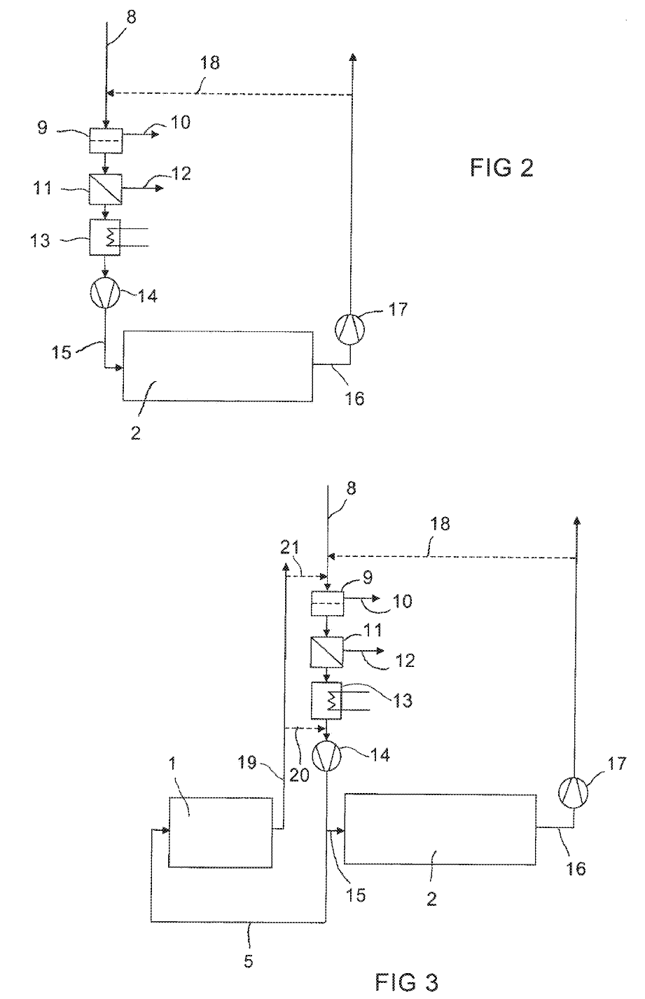

FIG. 2 schematically shows a method flow diagram of an advantageous embodiment of the method according to the invention for a coating apparatus as shown in FIG. 1;

FIG. 3 schematically shows a method flow diagram of a further advantageous embodiment of the method according to the invention for a coating apparatus as shown in FIG. 1;

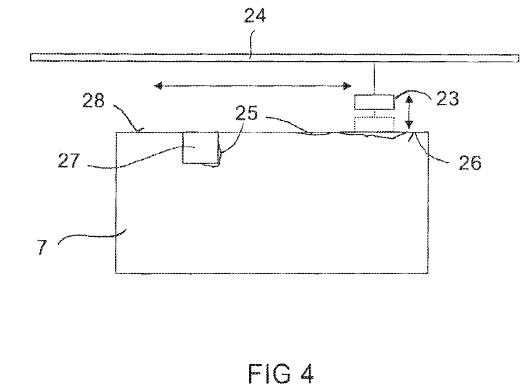

FIG. 4 schematically shows an advantageous embodiment of a mechanical pulse generator device of an apparatus according to the invention.

Corresponding parts and variables are denoted by the same reference designations in FIGS. 1 to 4.

FIG. 1 shows a glass washing apparatus 22, a glass drying apparatus 1 and a coating apparatus 2, as can be used in a glass processing process of the prior art. In the glass washing apparatus 22, glass substrates 3 which have previously been produced are washed, preferably with water or another suitable liquid, and then dried in the glass drying apparatus 1, so that they introduce the minimum possible amount of moisture into the coating apparatus 2, in the present case a magnetron coating installation, since this moisture can have an adverse effect on the coating operation. The glass substrates 3 are conveyed through a drying chamber 6 of the glass drying apparatus 1 on a conveyor belt 4 and exposed to conditioned drying gas 5. The conditioned drying gas 5 is blown into the drying chamber 6 at a number of points and flows over the glass substrates 3, with the moisture from the surface of the glass substrates 3 being taken up by the conditioned drying gas 5. The moisture-laden drying gas is then discharged from the drying chamber 6.

The dried glass substrates 3 then pass into the coating apparatus 2, in which they pass through a plurality of process chambers 7. In the process chambers 7, one or more layers of one or more substances are applied to the glass substrate 3 in the magnetron sputtering process. The sputtering process preferably takes place at a subatmospheric pressure of as low as 10−6 bar. To enable the subatmospheric pressure to be maintained in the individual process chambers 7 as the glass substrates 3 pass through, pressure locks (not shown here), through which the glass substrates 3 are passed and in which pressure equalization takes place, are provided at least between the glass drying apparatus 1 and a process chamber 7 and between the individual process chambers 7 and after the last process chamber 7.

Magnetron sputtering is a variant of DC or RF sputtering in which a transverse magnetic field is superimposed on the electric field of the glow discharge. For this purpose, an arrangement of permanent magnets, the magnetic field of which extends through the target into the plasma space, is installed generally behind the target, which acts as a cathode. The result of this is that the plasma is enclosed in front of the target in a type of magnetic cylinder and the electrons are forced onto circular or helical paths in front of the target. This leads to a considerable increase in the degree of ionization of the plasma and therefore an increase in the atomization and coating rate. Furthermore, the bombardment of the substrate with electrons is reduced, with the result that the thermal stressing of the substrate decreases. Magnetron sputtering variants which are frequently deployed include reactive magnetron sputtering and bias-assisted magnetron sputtering (cf. the Internet entry for the INO—Informationssystem für die wirkungsvolle Nutzung der Oberflächentechnik [Information system for the effective utilization of surface technology], www.schichttechnik.net). Magnetron sputtering can be used in particular to deposit various metals (e.g. silver) and metal oxides (e.g. zinc oxide) which in a suitable composition or layer structure serve in particular as layers protecting against sun and providing thermal insulation.

If the process chamber 7 is evacuated, substances, in particular water, which have been trapped, condensed or adsorbed on or in the inner walls or internal fittings of the process chambers 7 can pass into the gas phase and can interfere with the coating process, so that at least the first glass substrates 3 coated in the coating operation have to be disposed of as scrap.

If the coating apparatus 2 is cleaned by the method according to the invention prior to the coating operation, it is possible to reduce or even eliminate the production of scrap.

FIG. 2 shows a method flow diagram of an advantageous embodiment of the method according to the invention. The figure schematically shows the coating apparatus 2, which in its interior comprises at least one process chamber 7 (not illustrated in FIG. 2). In a first step, ambient air 8 is sucked in and then foreign substances 10 are removed from it in a filter 9. The foreign substances 10 are discharged from the filter 9 continuously or at regular intervals.

In a further method step, the purified ambient air passes into a conditioning device for setting the moisture content, in this case a refrigeration machine 11, which may be designed as an absorption refrigeration machine or as a compression refrigeration machine, both of which are known from the prior art. There, the ambient air is cooled to a predetermined temperature, during which process water condenses out. The condensate 12 is continuously discharged.

The ambient air 8 which has been dried in this way is then reheated in a heating device, preferably to a temperature of between 60° C. and 80° C., in order to accelerate the evaporation and/or desorption process in the coating apparatus 2. The warm and dry ambient air 8 now has a relative moisture content of preferably ≦25% and can take up a relatively large quantity of water up to saturation point.

In a compressor 14, the ambient air 8 is compressed to a predetermined pressure and blown into the coating apparatus 2. It is in this way also possible to set the flow velocity of the conditioned purge gas 15. A fan 17, which sucks in the laden purge gas 16 on the outlet side of the coating apparatus 2, can also assist with the flow through the process chambers 7.

The conditioned purge gas 15 is used in the coating apparatus 2 to purge both the at least one process chamber 7 and the pressure locks upstream of, downstream of and between individual process chambers, in order to remove impurities. The laden purge gas 16 is in the simplest case then completely released to the environment.

However, it is also possible for part or all of the volumetric flow of the laden purge gas 16 to be fed back to the conditioning devices 9, 11, 13, 14 via a purge gas recirculation 18. In this case, it is also possible for ambient air 8 to be admixed with the laden purge gas 16.

During the coating process in the coating apparatus 2, the conditioned purge gas 15 continues to be passed into the pressure locks, preferably for pressure equalization in the pressure locks and/or for purging the pressure locks and any glass substrate 3 located therein.

FIG. 3 illustrates a further advantageous embodiment of the method according to the invention. The figure likewise schematically shows the coating apparatus 2, which in its interior comprises at least one process chamber 7 (not shown). As described with reference to FIG. 2, ambient air 8 is correspondingly conditioned in the conditioning devices 9 (filter), 11 (refrigeration machine), 13 (heating device), 14 (compressor).

In the embodiment illustrated in FIG. 3, the conditioning devices 9, 11, 13, 14 are designed to process purge gas for the coating apparatus 2 and drying gas for the glass drying apparatus 1. Part of the ambient air 8 which has been conditioned as described above is introduced into the coating apparatus 2 as conditioned purge gas 15. The fan 17 assists with the flow through the coating apparatus 2, and some or all of the laden purge gas 16 is discharged or some or all of it is passed back to the filter 9 via a purge gas recirculation 18. Once again, ambient air 8 can be admixed with the laden purge gas 16.

During the coating process in the coating apparatus 2, conditioned purge gas 15 is once again passed into the pressure locks for pressure equalization in the pressure locks and/or for purging the pressure locks and any glass substrate 3 located therein.

The conditioned ambient air 8 which remains is fed into the glass drying apparatus 1 as conditioned drying gas 5. The laden drying gas 19 is discharged from the glass drying apparatus 1 and partly or completely released to ambient air. However, it is also possible, as illustrated in FIG. 3, for part or all of the volumetric flow of the laden drying gas 19 to be recirculated to the process. In this case, by way of example, some of the laden drying gas 19 can be added via a drying gas recirculation 20 to the ambient air 8 which has already been conditioned, and can in this way generate the conditioned purge gas 15. However, it is preferable for the laden drying gas 19 to be fed back via a drying gas recirculation 21 into the filter 9, in which case it may be mixed with the ambient air 8 and/or the laden purge gas 16.

FIG. 4 shows an advantageous embodiment of a mechanical pulse generator device of an apparatus according to the invention for removing solid impurities, known as deposits 25, in particular of coating material, on inner walls 26 or internal fittings 27 of a process chamber 7. FIG. 4 schematically illustrates a process chamber 7 in section. Such a deposit 25 of coating material is located on the process chamber inner wall 26 and on the internal fitting 27. A mechanical pulse generator 23, in this case a type of hammer, which can be guided along the process chamber 7 on a guide rail 24 (cf. the direction of the arrow along the process chamber), is provided for the purpose of eliminating the deposit 25. By suitable guidance, it is possible to guide the mechanical pulse generator 23 in both the longitudinal direction and transversely across the process chamber 7, in particular its process chamber outer wall 28. Furthermore, the mechanical pulse generator 23 may also extend over the entire length of the process chamber 7, so that it is only moved in a direction transversely to its longitudinal extent across the process chamber 7, in particular its process chamber outer wall 28. The mechanical pulse generator 23 can be moved perpendicular to process chamber outer wall 28 in the direction indicated by the arrow until it reaches the process chamber outer wall 28. The pulse provided by the impact is transmitted through the process chamber outer wall 28 to the process chamber inner wall 26 and/or to the internal fittings 27 and the deposit 25 of coating material which has accumulated thereon. As a result, the deposit 25 is at least partially detached and drops down under the force of gravity. The particles can then be removed from the process chamber 7.

### LIST OF DESIGNATIONS

1 Glass drying apparatus

2 Coating apparatus

3 Glass substrate

4 Conveyor belt

5 Conditioned drying gas

6 Drying chamber

7 Process chamber

8 Ambient air

9 Filter

10 Foreign substances

11 Refrigeration machine

12 Condensate

13 Heating device

14 Compressor

15 Conditioned purge gas

16 Laden purge gas

17 Fan

18 Purge gas recirculation

19 Laden drying gas

20 Drying gas recirculation

21 Drying gas recirculation

22 Glass washing apparatus

23 Mechanical pulse generator

24 Guide rail

25 Deposit

26 Process chamber inner wall

27 Internal fitting

28 Process chamber outer wall

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. A method for cleaning at least one process chamber for coating at least one substrate, in particular made from glass, wherein the at least one process chamber is purged with a conditioned purge gas prior to a coating operation.

36. The method as claimed in claim 35, in which the moisture content of the purge gas, before it enters the at least one process chamber, is set to a predetermined moisture level, in particular to a relative moisture content of at most 30%, in particular at most 25%, preferably at most 10% or at most 5%.

37. The method as claimed in claim 35, in which the purge gas, before it enters the at least one process chamber, has foreign substances removed from it, in particular by filtering.

38. The method as claimed in claim 35, in which the temperature of the purge gas, before it enters the at least one process chamber, is set in at least one predetermined temperature range, preferably to at least a predetermined temperature value, in particular in a temperature range between 20° C. and 90° C., preferably in a temperature range between 60° C. and 80° C.

39. The method as claimed in claim 35, in which the pressure of the purge gas, before it enters the at least one process chamber, is set to at least one predetermined pressure value, preferably in a pressure range between 0.8 bar and 1.5 bar.

40. The method as claimed in claim 35, in which the purge gas used is air, in particular ambient air, and/or an inert gas.

41. The method as claimed in claim 35, in which during a cleaning operation the conditioned purge gas flows, preferably continuously, through the at least one process chamber, and/or in which at least one cleaning step is carried out by flooding the process chamber with conditioned purge gas and then discharging the purge gas.

42. The method as claimed in claim 35, in which, during a or the cleaning operation, a pressure lock which is arranged at an entry and/or an exit of at least one process chamber for coating at least one substrate, in particular made from glass, is purged with conditioned purge gas or the conditioned purge gas.

43. The method as claimed in claim 35, in which, for pressure equalization in a pressure lock, arranged at an entry and/or an exit of the at least one process chamber conditioned purge gas flows into the pressure lock and/or in which the pressure lock, before the at least one substrate passes into the pressure lock and/or while the at least one substrate is in the pressure lock, is purged with conditioned purge gas.

44. The method as claimed in claim 35, in which the purge gas is mixed from various gas streams.

45. The method as claimed in claim 35, in which the purge gas is passed through a circuit or in a closed loop and in which preferably the purge gas which emerges from the at least one process chamber is conditioned with regard to the moisture content and/or the loading with foreign substances and/or the temperature and/or the pressure and/or the gas composition.

46. The method as claimed in claim 35, in which the at least one substrate is pretreated in a substrate treatment operation which precedes the coating operation, in particular in a substrate drying operation preceded by a substrate washing operation, in which preferably at least some of a conditioned drying gas for drying the at least one substrate in the substrate drying operation and/or at least some of a drying gas which is discharged from the substrate drying operation is at least partly used as conditioned purge gas.

47. The method as claimed in claim 35, in which the at least one process chamber is at least partially heated, preferably from the outside, in particular at least part of at least one process chamber wall, before and/or during a cleaning operation, in which preferably the at least one process chamber is heated at least in part to a temperature between 20° C. and 60° C., in particular between 40° C. and 60° C., in particular inductively and/or by radiation and/or by heat conduction.

48. The method as claimed in claim 35, in which at least one pulse generator device, before and/or during a coating operation, transmits at least one mechanical pulse to a process chamber wall, in particular an outer wall, of the at least one process chamber, in which preferably as pulse generator device at least one hammer and/or at least one compressed-air nozzle and/or at least one vibration unit and/or at least one ultrasound generator is used and/or in which preferably the mechanical pulse is triggered automatically as a function of at least one process variable and/or the strength of the mechanical pulse is set as a function of a degree of contamination and/or in which preferably at least some of the purge gas which emerges from the at least one process chamber is used to generate the mechanical pulse.

49. A method for cleaning at least one pressure lock arranged at an entry and/or an exit of at least one process chamber for coating at least one substrate, in particular made from glass, in which during a cleaning operation, the pressure lock is purged with conditioned purge gas.

50. A method for coating at least one substrate, in particular made from glass, in a process chamber, in which the process chamber, prior to a coating operation, is cleaned by purging the process chamber with conditioned purge gas and/or in which at least one pressure lock arranged at an entry or an exist of the process chamber is cleaned by purging, during a cleaning operation, the pressure lock with conditioned purge gas.

51. A method as claimed in claim 50, in which after the cleaning operation the pressure in the process chamber is reduced with respect to the ambient pressure, preferably to between 10⁻⁷ bar and 10⁻³ bar, and then a coating process is initiated, in particular a coating process from the vapor phase, preferably a PVD or CVD process.

52. An apparatus for cleaning at least one process chamber for coating at least one substrate, in particular made from glass, in particular for carrying out the method as claimed in claim 35, characterized in that at least one purge device is provided for introducing a conditioned purge gas into the at least one process chamber and/or for passing a conditioned purge gas through the at least one process chamber prior to a coating operation.

53. The apparatus as claimed in claim 52, in which the at least one purge device comprises at least one purge gas feed line and at least one purge gas delivery unit, in particular a pump and/or a fan, which are arranged upstream and/or downstream of the at least one process chamber as seen in a direction of flow.

54. The apparatus as claimed in claim 52, in which at least one conditioning device is provided for conditioning the purge gas before it enters the process chamber, in which at least one conditioning device is provided for the purpose of setting a moisture content of the purge gas, in particular in the form of an adsorption unit or a cooling unit, preferably an absorption refrigeration machine, and/or
in which at least one conditioning device is provided for setting a temperature of the purge gas, in particular in the form of a heating device, and/or
in which at least one conditioning device is provided for setting a pressure of the purge gas, in particular in the form of a compressor, and/or
in which at least one conditioning device is provided for separating foreign substances out of the purge gas, in particular in the form of a filter unit.

55. An apparatus, as claimed in claim 52, in which at least one feed device is provided for introducing conditioned purge gas or the conditioned purge gas into at least one pressure lock which is arranged at an entry and/or exit of a process chamber for coating at least one substrate, in particular made from glass, and/or for passing conditioned purge gas or the conditioned purge gas through the at least one pressure lock, and/or in which at least one discharge device is provided for discharging the purge gas from the at least one pressure lock.

56. The apparatus as claimed in claim 52, in which at least one heating device is provided for the purpose of heating at least part of at least one process chamber before and/or during a cleaning operation, which is preferably arranged outside the process chamber.

57. The apparatus as claimed in claim 52, in which at least one pulse generator device is provided, which prior to a coating operation imparts at least one mechanical pulse to a process chamber wall, in particular an outer wall, of the at least one process chamber, in which the at least one pulse generator device preferably comprises at least one hammer and/or at least one compressed-air nozzle and/or at least one vibration unit and/or at least one ultrasound generator and/or at least one control unit.

58. The apparatus as claimed in claim 52, in which there is at least one means for determining process variables, in particular for detecting a degree of contamination in the process chamber.

59. The apparatus as claimed in claim 52, in which the at least one conditioning device is at least one conditioning device of a substrate treatment apparatus connected upstream of the at least one process chamber, in particular of a substrate drying apparatus with upstream substrate washing apparatus.

60. The apparatus as claimed in claim 59, in which there is at least one device for introducing at least some of a drying gas which emerges from the substrate drying apparatus and/or at least some of a drying gas which has been prepared in the at least one conditioning device into the process chamber as at least part of the conditioned purge gas.
